(19) United States
(12) Patent Application Publication
(10) Pub. No.: US 2016/0192514 A1
(43) Pub. Date: Jun. 30, 2016

(54) ELECTRONIC APPARATUS HAVING A MOLDED RESIN HOUSING

(71) Applicant: KABUSHIKI KAISHA TOSHIBA, Tokyo (JP)

(72) Inventors: Minoru TAKIZAWA, Sagamihara Kanagawa (JP); Yasushi SASAKI, Mitaka Tokyo (JP); Meri UEDA, Yokohama Kanagawa (JP); Hiroshi OTA, Misato Saitama (JP)

(73) Assignee: KABUSHIKI KAISHA TOSHIBA, Tokyo (JP)

(21) Appl. No.: 14/700,499

(22) Filed: Apr. 30, 2015

(30) Foreign Application Priority Data
Dec. 26, 2014 (JP) 2014-266736

(51) Int. Cl. H05K 5/00; H05K 5/02; H05K 1/18

(52) U.S. Cl. CPC H05K 5/0034; H05K 1/181; H05K 5/0247; H05K 2201/10151

(57) ABSTRACT

An electronic apparatus includes a substrate having an edge including a non-flat portion, a plurality of electronic units disposed on a surface of the substrate, and a molded resin member covering the substrate and the plurality of electronic units thereon and having a gate scar at a position corresponding to the non-flat portion of the edge.

### CROSS-REFERENCE TO RELATED APPLICATION

This application is based upon and claims the benefit of priority from Japanese Patent Application No. 2014-266736, filed Dec. 26, 2014, the entire contents of which are incorporated herein by reference.

### FIELD

Embodiments described herein relate generally to an electronic apparatus having a molded resin housing.

### BACKGROUND

In the related art, an electronic apparatus is manufactured by injecting a resin around electrical components that are placed in a space inside a mold. An electronic apparatus manufactured through this process has an integrated structure of the electrical components and a molded resin member.

### DESCRIPTION OF THE DRAWINGS

FIG. 1 is a perspective view of an electronic apparatus according to a first embodiment.

FIG. 2 is a side view of a substrate in the electronic apparatus in a longitudinal direction of the substrate.

FIG. 3 is a side view of the substrate in a lateral direction of the substrate.

FIG. 4 is a plan view of the substrate including electrical components disposed thereon.

FIG. 5 is a plan view of the substrate placed in a mold when a synthetic resin material is injected in the mold to form a housing of the electronic apparatus according to the first embodiment.

FIG. 6 is a side view the substrate placed in the mold.

FIG. 7 illustrates a flow of a resin during molding the housing of the electronic apparatus according to the first embodiment.

FIG. 8 illustrates a positional relationship between the substrate of the electronic apparatus according to the first embodiment and a gate of the mold.

FIG. 9 illustrates a flow of a resin during molding a housing of an electronic apparatus according to a second embodiment.

FIG. 10 illustrates a flow of a resin during molding a housing of an electronic apparatus according to a third embodiment.

FIG. 11 is a plan view of a substrate of an electronic apparatus according to a fourth embodiment.

FIG. 12 is a plan view of a substrate of an electronic apparatus according to a fifth embodiment.

FIG. 13 is a plan view of a substrate of an electronic apparatus according to a sixth embodiment.

FIG. 14 is a plan view of a substrate of an electronic apparatus according to a seventh embodiment.

FIG. 15 is a plan view of a substrate of an electronic apparatus according to an eighth embodiment.

FIG. 16 illustrates a usage example of an electronic apparatus according to a ninth embodiment.

### DETAILED DESCRIPTION

One or more embodiments are directed to provide an electronic apparatus without a void or sink marks.

In general, according to one embodiment, an electronic apparatus includes a substrate having an edge including a non-flat portion, a plurality of electronic units disposed on a surface of the substrate, and a molded resin member covering the substrate and the plurality of electronic units thereon and having a gate scar at a position corresponding to the non-flat portion of the edge.

### First Embodiment

An electronic apparatus 10 according to the embodiment is, for example, a portable sensor unit which may detect a cardiac potential or the like. The electronic apparatus 10 includes a housing 12 of a flat cuboid shape that includes a surface 12a (sensor surface, top surface, surface wall), a rear surface 12b (bottom surface, rear surface wall), and side surfaces 12c, 12d, 12e, and 12f. For example, the housing 12 may have a polygonal shape, a circular shape, an elliptical shape, or the like when viewed above the surface 12a.

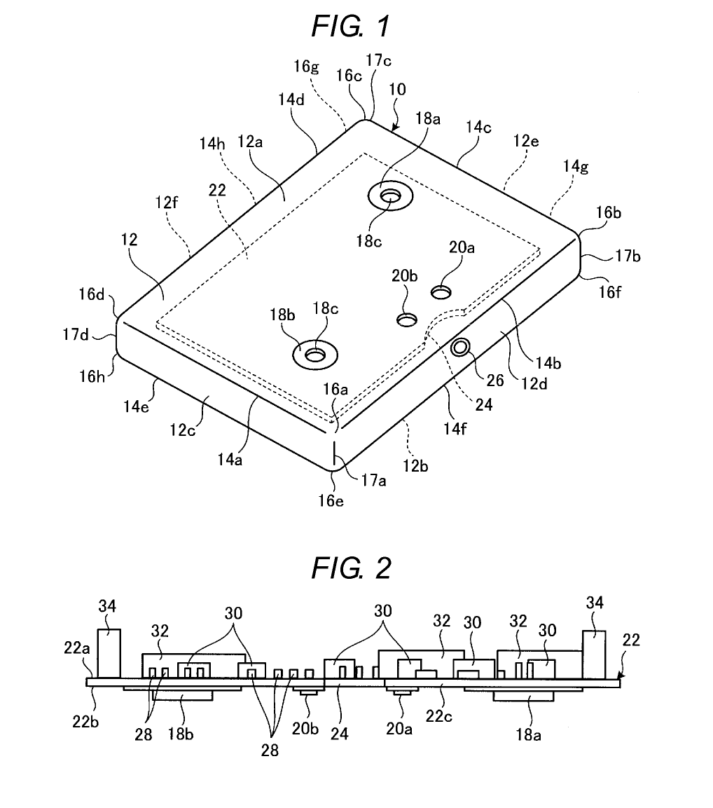

As illustrated in FIG. 1, end portions 14a, 14b, 14c, and 14d (sides, side portions, edges) of the surface 12a, and corners 16a, 16b, 16c, and 16d (apex portions, corner portions) at which end portions intersect each other, respectively have a chamfered shape. In addition, end portions 14e, 14f, 14g, and 14h (sides, side portions, edges) of the rear surface 12b, and corners 16e, 16f, 16g, and 16h (apex portions, corner portions) at which end portions intersect each other, respectively have a chamfered shape. In addition, a side 17a in a thickness direction of a housing 12 between corner 16a and a corner 16e, a side 17b between corner 16b and a corner 16f, a side 17c between corner 16c and a corner 16g, and a side 17d between corner 16d and a corner 16h also have a chamfered shape.

A sense of touch may be increased by these chamfer shapes, when a user touches the electronic apparatus 10. In addition, when the electronic apparatus 10 is mounted on a body surface to be used, even if contact a hand or an object, the electronic apparatus 10 is unlikely to be caught by the chamfer shapes, and detachment of the electronic apparatus 10 from the body surface may be suppressed. The chamfer shape may be a chamfer shape of a curved surface shape or a chamfer shape of a flat surface shape.

On the surface 12a of the housing 12, electrodes 18a and 18b (probes, terminals, metals, conductors) for detecting a biological signal in a state of being in contact with a subject, are disposed such that detection surface (contact portion, sensor surface, end portion, surface, one end surface) thereof is exposed on the surface 12a. The electrode 18a (first electrode) is, for example, a “+ electrode,” the electrode 18b (second electrode) is, for example, a “− electrode,” and both electrodes are separated from each other. When the electronic apparatus 10 detects a biological signal (potential, cardiac potential) in order to generate an electrocardiogram, a stable detection result may be obtained when a distance between the electrode 18a and the electrode 18b is equal to or longer than a predetermined distance. Meanwhile, the smaller the electronic apparatus 10 is, the more portability or usability of the electronic apparatus 10 increases.

According to the embodiment, the electrode 18a and the electrode 18b are arranged in a diagonal direction on the surface 12a. As a result, a size increase of the electronic apparatus 10 is suppressed, while a predetermined distance between the electrode 18a and the electrode 18b is secured. As illustrated in FIG. 1, the electrode 18a is disposed in a position close to the corner 16c, and the electrode 18b is disposed in a position close to the corner 16a. In this way, the electrode 18a and the electrode 18b are arranged in a diagonal position, and it is possible to lengthen a distance between the electrode 18a and the electrode 18b without increasing a size of the housing 12, compared to a case in which the electrodes 18a and the electrode 18b are arranged in a direction parallel to the end portion 14b or the end portion 14a.

In addition, the housing 12 may have flexibility (softness) and bendability. For example, it is possible to be bent such that a bus appears in a direction intersecting the end portions 14b and 14d of the housing 12. The electrode 18a is disposed in a position close to the corner 16c, that is, on one end extending in a longitudinal direction of the housing 12. The electrode 18b is disposed in a position close to the corner 16a, that is, on the other end extending in a longitudinal direction of the housing 12. As a result, when the electronic apparatus 10 is attached to a curved body surface, it is possible to more reliably attach the electrode 18a and the electrode 18b which are located at opposite ends of the housing 12 in the longitudinal direction, to the body surface.

In order to further increase adhesion of the electrode 18a and the electrode 18b to the body surface, an adhesive material (gel material) with conductivity may be disposed between the electrode 18a and the electrode 18b, and the body surface. Since the adhesive material is relatively and easily deformed, the electrode 18a (+ electrode) may be electrically connected to the electrode 18b (− electrode) when the housing 12 is bent. Further such an electrical connection may be caused by sweat generated from the body surface. As a result, a biological signal may not be properly detected depending on the shape of the housing (and the adhesive material thereon). In order to suppress such inconvenience, it is preferable that a distance between the electrode 18a and the electrode 18b is set to be long. As another embodiment, the electrode 18a may be located in a position close to the corner 16b and the electrode 18b may be located in a position close to the corner 16d.

Data input and output terminals 20a and 20b (connectors, contact points, electrodes, metals, conductors) are exposed on the surface 12a. The input and output terminals 20a and 20b include contact portions that are to be in contact with an external conductor, and may be electrically connected to a terminal of an adaptor apparatus such as a cradle or the like. The input and output terminals 20a and 20b may be used when a detected value that the electronic apparatus 10 acquires, or data, information, or the like based on the detected value is transferred to an external apparatus using a wired method, or when update of software for controlling the electronic apparatus 10 is performed using the wired method.

Here, the external conductor is a conductor outside the electronic apparatus 10 and not included in the electronic apparatus 10. For example, the external conductor is electrically connected to the input and output terminals 20a, 20b, electrodes 18a and 18b, and other conductor (not illustrated) which are included in the electronic apparatus 10, and receives and transmits a power, data, a signal or the like. The external conductor is electrically connected to other electronic apparatuses, or conductor portions embedded in a power device or the like.

As illustrated in FIG. 1, the input and output terminals 20a and 20b are arranged in a direction substantially parallel to the end portion 14b and close to the end portion 14b. The input and output terminals 20a and 20b are not used when the electronic apparatus 10 is in contact with a subject. In addition, a current does not flow between the input and output terminal 20a and the input and output terminal 20b. Thus, the input and output terminals 20a and 20b may not be necessarily separated like as the electrodes 18a and 18b, and may be disposed relatively close to each other. The input and output terminals 20a and 20b may be disposed in any position of the electronic apparatus 10, but it is possible to efficiently assemble the electronic apparatus 10 when the electrodes 18a and 18b and the input and output terminals 20a and 20b are similarly shaped, and located on the same surface of a substrate 22, which is supported by the housing 12.

As illustrated in FIG. 2 to FIG. 4, the substrate 22 includes a first surface 22a (surface), a second surface 22b (rear surface), end portions 22c, 22d, 22e, and 22f (sides, side portions, edges), and corners 22g, 22h, 22i, and 22j (apex portions, corner portions, end portions) at which end portions intersect each other. In the embodiment, for convenience, the end portion 22c may be referred to as a first end portion, and the end portion 22e opposite to the end portions 22c may be referred to as a second end portion. In addition, the first surface 22a, which extends between the end portions 22c (first end portion) and the end portion 22e (second end portion), may be referred to as a first surface, and the second surface 22b, which extends between the end portions 22c (first end portion) and the end portion 22e (second end portion) may be referred to as a second surface. The second surface is opposite to the first surface 22a (first surface).

Then, a non-flat portion 24 that includes at least one of a convex portion protruding towards a side away from the end portion 22e and a concave portion recessed towards the end portion 22e, is provided in the end portion 22c. FIG. 1 to FIG. 8, which correspond to the first embodiment, illustrate a case in which the non-flat portion 24 is a concave portion. When the non-flat portion 24 is a concave portion, the concave portion may be formed in an arch shape.

In addition, the substrate 22 on which a plurality of electrical components illustrated in FIG. 2 to FIG. 4 is mounted may be referred to as a sub-assembly. Here, the end portions 22c and 22e are portions (areas) that are ends of the substrate 22 viewed in a thickness direction of the substrate 22, that is, a direction (crossing direction) orthogonal to a surface of the substrate 22, and are also referred to as, for example, sides or edges. The end portions 22c and 22e may not be shaped in a straight line. In addition, the end portions 22c and 22e may not be parallel to each other.

In addition, the first surface 22a and the second surface 22b are provided in an extended manner between the end portions 22c and 22e, that is, the end of one side of the first surface 22a is the end portion 22c, and the end of the other side of the first surface 22a is the end portion 22e. That is, the first surface 22a and the second surface 22b exist between the end portions 22c and the end portion 22e. The first surface 22a and the second surface 22b may be positioned in an opposite side with respect to each other, and may respectively include some roughness portions, a difference in level, or the like. In addition, a concave portion, a thorough-hole, a notch, or the like may be provided on the first surface 22a and the second surface 22b.

In addition, in a view in a thickness direction of the substrate 22, the non-flat portion 24 on the end portion 22c is not flat, that is, is not shaped in a straight line, is a portion including at least one of a concave shape and a convex shape, and includes, for example, a notch (concave portion), a protrusion (convex portion), a difference in level, or the like that is provided in the end portion 22c, which is an outer edge. A concave direction of a concave shape and a convex direction of a convex shape are directions (orthogonal direction) intersecting the end portion 22c in a view in the thickness direction of the substrate 22. The non-flat portion 24 may include a slope extending in the thickness direction of the substrate 22, a difference in level, or the like. In addition, the non-flat portion 24 may be a roughness, when compared to a peripheral portion (adjacent portion, general portion) thereof, and the end portion 22c may not be shaped in a straight line in a view from the thickness direction of the substrate 22, and may be curved.

A biological signal that is detected through the electrodes 18a and 18b is stored in a storage unit (not illustrated), which is mounted on the substrate 22 in an inside of the electronic apparatus 10, is transferred to an external apparatus such as an electrocardiogram output device (electrocardiograph, monitoring device, printing device) at a desired timing, or transferred to a personal computer, a server, or the like. In addition, the biological signal may be transferred also to an electrocardiogram output device, a portable terminal, or the like in real time. The electronic apparatus 10 according to the embodiment may transfer the biological signal to an external apparatus using a wired method through the input and output terminals 20a and 20b. In addition, the biological signal may be transferred to an external apparatus through a communication unit such as Bluetooth (registered trademark). In this case, for example, the electrocardiogram may be monitored for 24 hours. It is possible to perform a data transfer with a predetermined interval, a transfer in a desired timing, or updating of software of the electronic apparatus 10, or the like, through a communication unit such as Bluetooth.

The housing 12 is formed of a synthetic resin material (silicone rubber, elastomer, flexibility resin) with, for example, flexibility (softness). The housing 12 is molded in a state in which a sub-assembly including a plurality of electrical components is located within the housing 12 as a core, by insert molding (injection molding). That is, the housing 12 is molded such that the sub-assembly is located within and covered by the synthetic resin material. The substrate 22 has, for example, a flat rectangular plate shape.

The housing 12 includes outer surfaces (surface 12a, rear surface 12b, side surfaces 12c, 12d, 12e, and 12f). A trace of a gate, which is formed during injection molding, exists at a position of the side surface 12d corresponds to the end portion 22c of the substrate 22 on which the non-flat portion 24 is formed. The outer surface of the housing 12 includes a side surface 12d (third surface) positioned on a side of the substrate 22 opposite to the end portion 22e (second end portion), i.e., on the end portion 22c (first end portion). A concave portion 26 is formed as a trace of a gate in a first middle portion between two fifth end portions (side 17a, side 17b) of a front and rear of a second direction P along the end portion 22c, on the side surface 12d. Here, the outer surface is a surface exposed to the outside of the housing 12, and may also be referred to as a surface. In addition, the outer surface may not be an outermost surface of the electronic apparatus 10. That is, the terminal, the electrode, or the like may protrude from the housing 12.

In addition, a three-dimensional shape of the outer surface may be variously set. For example, a concave portion, a convex portion, a difference in level, or the like may be formed on the outer surface. The concave portion or the convex portion formed on the outer surface is not flat, that is, is not a flat surface, and has at least one of the concave shape and the convex shape. The concave portion is, for example, a recessed portion which does not penetrate, a through-hole, a difference in level, or the like. The concave portion is, for example, a recess, a difference in level, or the like. The convex portion or the concave portion may be a roughness when compared to a peripheral portion (adjacent portion, general portion) thereof, the outer surface is not necessary to have a flat shape, and may be curved, in a position in which the concave portion or the convex portion is provided.

Here, the gate is an injection hole (inlet) formed in a mold through which a resin, which configures the housing 12, flows into a cavity portion of the mold. The trace is an irregularity of a shape or the material of the housing 12 corresponding to the gate, may be anything (mark) from which the position of the gate can be estimated, and it may not be visually recognized.

In the embodiment, the trace of the gate may be, for example, the concave portion 26 formed on the side surface 12d, and may have an annular shape. The “annular” shape includes not only a circular shape but also an endless shape.

FIG. 2 to FIG. 4 illustrate the substrate 22 which is supported inside the housing 12 of the electronic apparatus 10, and a plurality of electrical components mounted on or supported by the substrate 22. The substrate 22 includes the first surface 22a (surface, first mounting surface), and the second surface 22b opposite to the first surface 22a (FIG. 2). In the embodiment, as an example of a plurality of electrical components, a microprocessor (MPU) that controls the whole electronic apparatus 10, a communication chip that transmits data such as a detected biological signal and receives the data from an external apparatus, a chip capacitor, a chip resistor, and the like are mounted on a first surface 22a.

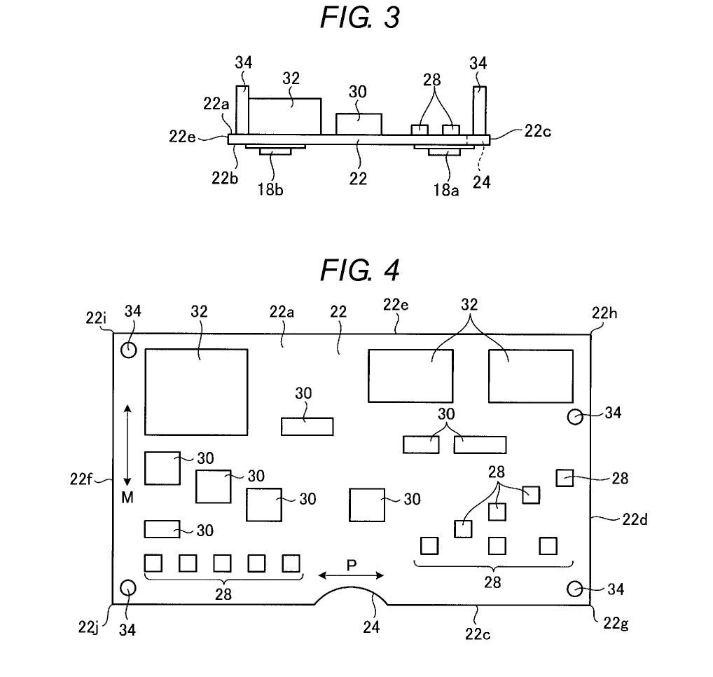

In the embodiment, the plurality of electrical components supported on the first surface 22a is categorized into three types of components, i.e., small components 28, medium components 30, and large components 32 for convenience, based on a size (surface area, volume, side area) or a height. In the embodiment, as an example, the small components 28, the medium components 30, and the large components 32 are mounted on the substrate 22, such that the height of the electrical components becomes gradually larger from the end portion 22c of the substrate 22, on which non-flat portion 24 is formed as illustrated in FIG. 3, toward the end portion 22e of the substrate 22.

In addition, the first surface 22a supports terminals 34 of a circular shape as other components. The substrate 22 according to the present embodiment supports, for example, four terminals 34 (FIG. 2 and FIG. 3 illustrate only two terminals). For example, two of the terminals 34 may be used as terminals for charging a battery (not illustrated), which is included in the electronic apparatus 10. In this case, the terminal 34 may be located so as to be electrically connected a terminal for charging included in a cradle. In addition, the terminals 34 may be used as terminals for connection to an external battery. In addition to this, the terminal 34 may be used as a terminal for transmitting and receiving data. On the other hand, the second surface 22b supports the electrodes 18a and 18b and input and output terminals 20a and 20b, which are metal components, as illustrated in FIG. 2 and FIG. 3.

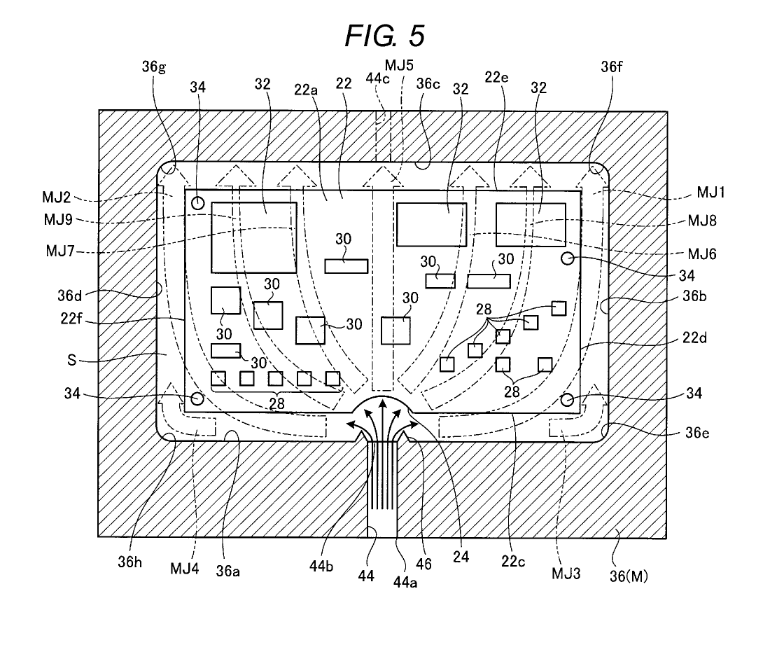

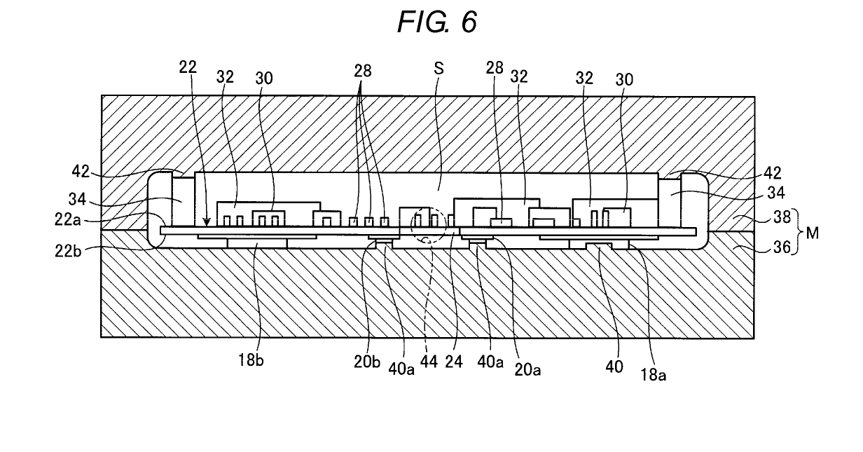

Next, the insert molding to form the housing 12 of the electronic apparatus 10 will be described. As illustrated in FIG. 5 and FIG. 6, the sub-assembly (substrate 22 which supports small components 28, medium components 30, large components 32, terminals 34, electrodes 18a and 18b, input and output terminals 20a and 20b) illustrated in FIG. 2 to FIG. 4 is inserted into an insert molding mold M, a synthetic resin material MJ is filled around the sub-assembly, whereby the electronic apparatus 10 including the substrate 22 embedded in the synthetic resin material MJ is produced.

The insert molding mold M includes a first mold 36 (lower mold, fixed mold) and a second mold 38 (upper mold, lifting mold), as illustrated in FIG. 6. As illustrated in FIG. 5, the first mold 36 is a metal block formed in a shape corresponding to an outer shape of the housing 12, and includes side wall portions 36a, 36b, 36c, and 36d, and corner 36e, 36f, 36g, and 36h. The side wall portions 36a, 36b, 36c, and 36d, and the corner 36e, 36f, 36g, and 36h are chamfered corresponding to the shape of the housing 12, and as necessary, draft extending in an opening end side (surface side of first mold 36) is formed. The second mold 38 is also a metal block formed in a shape corresponding to an outer shape of the housing 12, in the same manner as the first mold 36.

Then, when manufacturing an electronic apparatus 10, the substrate 22 (sub-assembly) having the first surface 22a on which a plurality of electrical components (small components 28, medium components 30, large components 32, terminals 34) are mounted or supported and the second surface 22b on which electrodes 18a and 18b and the input and output terminals 20a and 20b are mounted or supported, is placed in a gap portion S which is formed when the insert molding mold M is closed.

In this case, a positioning protrusion 40 (only the positioning protrusion 40 for pin, concave portion, or electrode 18a is illustrated in FIG. 6) formed in a predetermined position of the first mold 36 fits a concave portion 18c formed in a tip portion of the electrode 18a (18b), which is supported on the second surface 22b of the substrate 22. As a result, positioning and support of the substrate 22 in the gap portion S of the insert molding mold M is fixed. Similarly, the positioning protrusion 40 fits the concave portion 18c. As a result, a detection surface of the electrode 18a (18b) may be exposed on the surface 12a, and the substrate 22 may be positioned in a predetermined position in the housing 12. That is, the electrodes 18a and 18b function as positioning members to position the substrate 22 in the housing 12.

A protrusion 40a (pin, convex portion) is also formed in a position corresponding to the input and output terminals 20a and 20b, and the protrusion 40a is in contact with the input and output terminals 20a and 20b. As a result, as illustrated in FIG. 1, it is possible to form the housing 12 having recessed portions in which the input and output terminals 20a and 20b are exposed on the surface 12a. According to this recessed portion of the housing 12, the input and output terminals 20a and 20b may be prevented from being inadvertently and electrically connected, when a finger or the like of a user contacts the terminals. That is, the input and output terminals 20a and 20b also function as positioning members to position the substrate 22 in the housing 12.

As illustrated in FIG. 1, since the electrodes 18a and 18b are diagonally disposed and the input and output terminals 20a and 20b are disposed, the substrate 22 is supported at four points by the first mold 36, thereby being stably supported in the first mold 36.

Similarly, a protrusion 42 (pin, convex portion) is also formed in a predetermined position of the second mold 38 (in FIG. 6, only two protrusions are illustrated), and the protrusion 42 is in contact with a tip of the terminal 34. As a result, the housing 12 may be formed such that the tip of the terminal 34 is recessed from the rear surface 12b. That is, the terminal 34 may be prevented from being inadvertently and electrically connected, when a finger or the like of a user contacts the terminal 34. As illustrated in FIG. 4, the terminals 34 are disposed in the vicinity (only a portion of the corner 22h is shifted in order to avoid interference with other components) of the corners 22g, 22h, 22i, and 22j of the substrate 22. Thus, the terminals 34 are used to determine a position of the substrate 22 in the gap portion S of the second mold 38. That is, the terminals 34 function as positioning members to position the substrate 22 in the housing 12. In this way, according to the embodiment, since the substrate 22 is supported by a plurality of supporting points by both the first surface 22a and the second surface 22b, the substrate 22 may be stably located, even when the synthetic resin material MJ is filled and cured.

A gate 44, which is a supply inlet during filling the gap portion S with the synthetic resin material MJ, is provided in the insert molding mold M. FIG. 5 illustrates an example in which the gate 44 is provided in the first mold 36, but the gate 44 may be provided in the second mold 38. In addition, the gate may be formed by a recessed portion formed in the first mold 36 and a recessed portion formed in the second mold 38 (for example, divided into two equal portions). The position of the gate 44 may be appropriately determined according to a configuration of the insert molding mold M, a shape of the substrate, or a position of the substrate 22 in the gap portion S.

According to the embodiment, when the insert molding is performed by filling in the gap portion S of the insert molding mold M with the synthetic resin material MJ after the substrate 22 is placed in the gap portion S, the synthetic resin material MJ should flows well. However, when the small components 28, the medium components 30, the large components 32, the terminals 34, the electrodes 18a and 18b, the input and output terminals 20a and 20b, and the like, which are different in shape and size, are supported on the substrate 22, the synthetic resin material MJ may not spread to every corner of the mold M. That is, a void or sink marks may be produced in the housing 12, thereby lowering quality thereof. In order to avoid such a problem, a molding time may need to be longer or the synthetic resin material MJ may need to be injected with high pressure, and this may decrease manufacturing efficiency.

To deal with this issue, the substrate 22 included in the electronic apparatus 10 according to the embodiment includes a non-flat portion 24 for changing a flow direction of the synthetic resin material MJ flowing into the gap portion S from the gate 44. The non-flat portion 24 is formed in a second intermediate portion between sixth end portions (corners 22g and 22j) of the end portions 22c extending in a second direction P (FIG. 4). In addition, in the insert molding mold M, the gate 44 is formed in a position facing the non-flat portion 24 of the substrate 22 inserted in the gap portion S.

When the synthetic resin material MJ flows into the gap portion S, the synthetic resin material MJ flows toward a gate outlet 44b from an inlet 44a of the gate 44 and spread between (gap portion S) the first surface 22a of the substrate 22 and a bottom surface of the second mold 38 and between (gap portion S) the second surface 22b and a bottom surface of the first mold 36. In addition, the synthetic resin material MJ flows between the end portion 22c of the substrate 22 and a side wall portion 36a of the first mold 36, between the end portions 22d and a side wall portion 36b, between the end portion 22e and the a side wall portion 36c, and between the end portion 22f and a side wall portion 36d.

In this case, when the gate 44 has a straight tube shape, a flow direction of the synthetic resin material MJ in the gap portion S of the insert molding mold M tends to be in a direction toward the side wall portion 36c, which is opposite to the side wall portion 36a having the gate 44, and the synthetic resin material MJ is not likely to flow in a direction of the side wall portion 36b or the side wall portion 36d. As a result, unevenness (void, sink marks) of the synthetic resin material MJ may be produced on the side wall portion 36b or the side wall portion 36d.

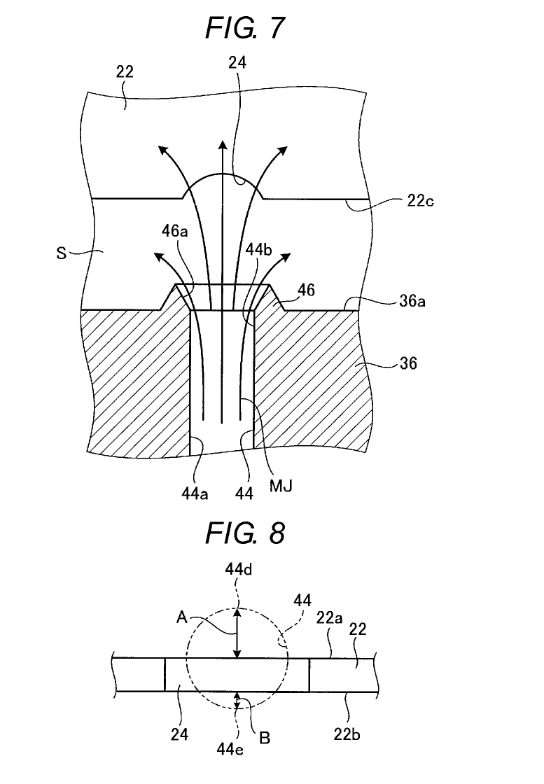

The substrate 22 according to the embodiment includes the non-flat portion 24 having a recessed arch shape in a position facing the gate 44, as illustrated in FIG. 5 and FIG. 7. When the non-flat portion 24 is formed, the synthetic resin material MJ tends to flow in a direction perpendicular to the non-flat portion 24. That is, the flow direction of the synthetic resin material MJ may be changed according to the arch shape of the non-flat portion 24, and the synthetic resin material MJ flows in a direction towards the side wall portion 36b or the side wall portion 36d of the insert molding mold M. As a result, a filling efficiency may be increased, and a void or sink marks may be suppressed when the molding of the housing 12 is completed.

Since the non-flat portion 24 is formed in the substantially central portion of the side 22c of the substrate 22, the synthetic resin material MJ substantially evenly flows towards the side wall portion 36b and towards the side wall portion 36d around the position of the non-flat portion 24, and thus efficient filling is can be performed. In addition, it is preferable to determine a concave depth or a concave width of the non-flat portion 24 in a second direction P (FIG. 4) towards the end portion 22e, according to the size (a distance between the side wall portion 36a and the side wall portion 36c, or a distance between the side wall portion 36b and the side wall portion 36d) of the housing 12 to be formed. A diffusing direction of the synthetic resin material MJ may be adjusted according to the roughness shape of the non-flat portion 24.

Furthermore, in the embodiment, in order to increase diffusivity during filling of the synthetic resin material MJ, the protrusion 46 is provided in an end portion of the gate outlet 44b of the gate 44 of the insert molding mold M (first mold 36). As an example, in FIG. 7, a circular protrusion 46 is provided so as to surround the gate outlet 44b. In the protrusion 46, at least an inner diameter wall is a taper surface wall 46a in which a tip end of the protrusion 46 has a larger diameter than the gate outlet 44b. FIG. 7 illustrates a case in which a cross-sectional shape of the protrusion 46 is a triangular shape as an example.

In this way, the protrusion 46 including the taper surface wall 46a around the gate outlet 44b is provided. When the synthetic resin material MJ flows toward the gate outlet 44b from the gate inlet 44a and into the gap portion S, a portion of the synthetic resin material MJ flows along the taper surface wall 46a, as illustrated in FIG. 6. That is, when flowing from the gate 44, flow directions of the synthetic resin material MJ are deflected along the taper surface wall 46a by viscosity or a flow resistance of the synthetic resin material MJ. As a result, the flow directions of the synthetic resin material MJ include a straight direction toward the side wall portion 36c (FIG. 5) along the formed direction of the gate 44 and the deflected direction along the taper surface wall 46a of the protrusion 46 toward the side wall portion 36b and the side wall portion 36d. That is, when the gap portion S is filled with the synthetic resin material MJ, the synthetic resin material MJ may be diffused in a wide range. As a result, the filling efficiency of the synthetic resin material MJ is increased, and a void or sink marks may be suppressed when the molding of the housing 12 is completed.

In addition, the protrusion 46 is formed in the gate 44 facing the non-flat portion 24 described above, and thereby the diffusion of the synthetic resin material MJ can be caused by both the non-flat portion 24 and the protrusion 46, and more efficient filling of the synthetic resin material MJ and a wide range of diffusions may be achieved.

In this way, by providing the protrusion 46 in the insert molding mold M (for example, first mold 36), the concave portion 26 is formed as the trace of the gate recessed in a depth direction of the non-flat portion 24 in the housing 12, as illustrated in FIG. 1. In FIG. 1, the substrate 22 is disposed close to the surface 12a of the housing 12. On the other hand, the concave portion 26 of FIG. 1 is formed on a side closer to the side 14b than the side 14f in a thickness direction (direction along sides 17a and 17b) of the housing 12, in a position determined according to an amount of filling of the synthetic resin material MJ on each of front and rear surfaces of the housing 12.

In FIG. 1, a trace of a circular shape corresponding to the gate 44 remains in the center portion of the annular concave portion 26. That is, by forming the housing 12 so as to leave the concave portion 26, the synthetic resin material MJ may be effectively diffused in the insert molding mold M during insert molding, efficient filling of the synthetic resin material MJ may be achieved, and a void or sink marks may be suppressed.

Since the concave portion 26 has a size which may be sensed by a hand, a finger, or the like of a user, the concave portion 26 may be used as an indicator for recognizing a surface orientation of the electronic apparatus (for example, side surface wall 12d) when the electronic apparatus 10 is attached to a body surface of the user. In addition, the concave portion 26 may be used as a portion of design of the side surface wall 12d of the housing 12. For example, the concave portion 26 may be used as a letter “0” in the design.

In addition, the protrusion 46 is not limited to an annular shape surrounding the gate outlet 44b, and may intermittently surround the gate outlet 44b. In addition, although the cross-section of the gate 44 illustrated in FIG. 1 is a circular shape, the shape of the gate 44 may be, for example, an elliptical shape, rectangular shape, triangular shape, or the like. As long as the protrusion 46 surrounds the periphery of the gate 44, the same effect as in the embodiment described above may be obtained. In FIG. 7, the cross-section of the taper surface wall 46a is shaped in a straight line, but is not limited to this. For example, the cross-section of taper surface wall 46a may be a curved line. A diffusion direction of the synthetic resin material MJ may be adjusted by the shape of the taper surface wall 46a or a taper angle.

When the housing 12 is formed by filling the gap space S on the first surface 22a e (surface side) and on the second surface 22b (rear surface side) of the substrate 22 with the synthetic resin material MJ, an amount of the synthetic resin material MJ may not be equal on the side of the first surface 22a and the side of the second surface 22b side.

As illustrated in FIG. 5, as a plurality of electrical components, the small components 28, the medium components 30, the large components 32, the terminals 34, and the like are mounted on the first surface 22a, in the electronic apparatus 10 according to the embodiment. Meanwhile, as illustrated in FIG. 6, only the electrodes 18a and 18b and the input and output terminals 20a and 20b are mounted on the second surface 22b, and the number of electrical components on the second surface 22b side is smaller than that on the first surface 22a. That is, volumes to be filled with the synthetic resin material MJ are different between the side of the first surface 22a and the side of the second surface 22b.

In addition, in the electronic apparatus 10 according to the embodiment, as illustrated in FIG. 5, the substrate 22 is placed in the gap portion S of the insert molding mold M closer to the first mold 36 than the second mold 38, and then the synthetic resin material MJ is injected on the first surface 22a and the second surface 22b. That is, an amount of the synthetic resin material MJ required to fill the space above the first surface 22a and the space above the second surface 22b is different from each other. In this way, a mounting situation (the number of mounting or occupied volume) of electrical components or a position of the substrate 22 in the gap portion S may be different depending on specification of the electronic apparatus 10. That is, an amount of the synthetic resin material MJ above the first surface 22a and above the second surface 22b may be different.

In the embodiment, the concave portion 26, which is a trace of the gate, includes a third end portion 44d above the first surface 22a in a view in the first direction M (refer to FIG. 4) along the first surface 22a or the second surface 22b of the substrate 22, and a fourth end portion 44e below the second surface 22b in a view in the first direction M. That is, the concave portion 26 extends across the side edge of the substrate 22 (FIG. 6 and FIG. 8). That is, the gate 44 is located in the insert molding mold M so as to correspond to the non-flat portion 24. According to this position of the gate 44, the synthetic resin material MJ may efficiently flow into the space above the first surface 22a and the space below the second surface 22b. Further, by the diffusion of the synthetic resin material MJ caused by the non-flat portion 24 and the protrusion 46 described above, more efficient filling of the synthetic resin material MJ may be carried out.

Here, in a view in a direction along the first surface 22a or the second surface 22b of the substrate 22, the situation that a trace of the gate 44 is located across an area (area on the first surface 22a, first area) above the first surface 22a and an area (area on the second surface 22b, second area) below the second surface 22b, is expressed as “the trace of the gate 44 extends across the substrate 22.”

In addition, in the electronic apparatus 10 according to the embodiment described above, an amount of the synthetic resin material MJ filled on the first surface 22a is greater than that filled on the second surface 22b. Thus, when the gate 44 faces the non-flat portion 24, as illustrated in FIG. 8, the gate 44 is offset to a side in which the amount of the synthetic resin material MJ to be injected is greater. In FIG. 8, an opening width A of the gate 44 above the first surface 22a in which an amount of the synthetic resin material MJ to be filled is greater, is larger than an opening width B of the gate 44 below the second surface 22b in which the amount of the synthetic resin material MJ to be filled is smaller. That is, an amount of the synthetic resin material MJ flowing out of the gate 44, per unit time, is greater in the space above the first surface 22a than in the space below the second surface 22b. As a result, the filling of the synthetic resin material MJ above the first surface 22a of the substrate 22 and below the second surface 22b of the substrate 22 may be performed more efficiently. The opening width A and the opening width B may be determined based on an experiment or the like, based on the volume of the synthetic resin material MJ necessary for the space above the first surface 22a and the space below the second surface 22b, flow resistance of the synthetic resin material MJ above the first surface 22a and below the second surface 22b, or the like.

As described above, when the housing 12 is formed, flow resistance of the synthetic resin material MJ may increase by the electrical components mounted on the substrate 22, even when the synthetic resin material MJ is diffused in a wide range according to the non-flat portion 24 and the protrusion 46. For example, if a large electrical component (for example, tall component or wide component) is disposed on an upstream side of the flow of the synthetic resin material MJ, the flow of the synthetic resin material MJ may be disturbed by the electrical component, a flow velocity of the synthetic resin material MJ may decrease, and furthermore, the synthetic resin material MJ may not reach the periphery of the electrical components located downstream as electrical components located upstream may block the flow of the synthetic resin material MJ.

In the electronic apparatus 10 according to the embodiment, the electrical components are disposed on the substrate 22 in accordance with a predetermined manner, as illustrated in FIG. 2 to FIG. 4. For example, the substrate 22 includes a first electrical component, which is one of the plurality of components (small components 28, medium components 30, large components 32, or the like) provided in one of the first surface 22a and the second surface 22b, and a second electrical component, which is one of the plurality of components provided in one of the first surface 22a and the second surface 22b. A height of the second electrical component from a surface of the substrate 22 is higher than that of the first electrical component, and the second electrical component is disposed farther from the non-flat portion 24 than the first electrical component. As an example, package components are mounted on the first surface 22a of the substrate 22. In addition, the substrate 22 includes the side 22c (first end portion), in which the non-flat portion 24 is provided, and the side 22e (second end portion) opposite to the side 22c. Thus, package components are disposed closer to the side 22e than the side 22c.

Here, the package component may be a large component 32 such as a microprocessor (MPU) or a chip for communication (Bluetooth). Since the large component 32 includes a package substrate covered with resin, a width of the large component (side surface area) tends to be large and a height of the large component tends to be high. In contrast, the small component 28, such as a chip capacitor or a chip resistor other than the package component, or the medium component 30 tends to have a smaller side surface area and a lower height.

In view of this, the large component 32 which may disturb the flow of the synthetic resin material MJ is disposed away from the gate 44, and the medium component 30 or the small component 28, which is not likely to disturb the flow of the synthetic resin material MJ, is disposed upstream (side close to gate 44) with respect to the large components 32. For example, the electrical components are disposed in the sequence of the small components 28, the medium components 30, and the large components 32 from a region close to the gate 44. As a result, the synthetic resin material MJ flowing out of the gate outlet 44b is diffused by the non-flat portion 24 or the protrusion 46 without being disturbed by the electric components, and a space (side 22e of the substrate 22) apart from the gate 44 may be filled more surely with the synthetic resin material MJ.

As illustrated in FIG. 2, the electrodes 18a and 18b and the non-flat portion 24, both of which are mounted on the second surface 22b of the substrate 22, are disposed apart from each other. As a result, also in the second surface 22b side, the synthetic resin material MJ flowing out of the gate outlet 44b is diffused by the non-flat portion 24 or the protrusion 46 without disturbed by the electrodes 18a and 18b, and a space (side 22e of the substrate 22) apart from the gate 44 may be filled more surely with the synthetic resin material MJ.

FIG. 5 schematically illustrates an example a flow of the synthetic resin material MJ flowing out of the gate outlet 44b into the insert molding mold M. In this case, immediately after flowing out of the gate outlet 44b, the synthetic resin material MJ that is diffused toward the side wall portion 36b or the side wall portion 36d by the non-flat portion 24 or the protrusion 46 is not in contact with the large components 32, which greatly decrease the flow velocity of the synthetic resin materials MJ.

Specifically, the synthetic resin materials MJ1, MJ2, MJ3, and MJ4, which pass through the side 22c, the side 22d, the side 22f, and the like of the substrate 22, are not in contact with any electrical components or are contact with a few of the small components 28, without losing flow speed from the gate outlet 44b.

In addition, in the example of FIG. 5, the synthetic resin material MJ5 reaches the side wall portion 36c just by being in contact with the medium component 30. Even in this case, the synthetic resin material MJ5 flows without losing flow speed from the gate outlet 44b.

Meanwhile, the synthetic resin materials MJ6 and MJ7 flow while contacting several of the small components 28, the medium component 30, and the large component 32 and then approach the side wall portion 36c. During the flow, the flow velocity of the synthetic resin materials is decreased (gradual narrowing of a width of arrows indicates a velocity decrease).

In addition, the synthetic resin materials MJ8 and MJ9 flow while contacting several of the small component 28, the medium component 30, the large component 32, and then approach the side wall portion 36c. During the flow, the flow velocity of the synthetic resin materials is decreased (further gradual narrowing of a width of arrows indicates a velocity decrease).

In this way, the large component 32 (package component), which is likely to disturb the flow of the synthetic resin material MJ, is disposed in a position apart from the gate 44. As a result, the filling of the synthetic resin material MJ for molding the housing 12 may be made more surely, and a void or sink marks of the housing 12 may be suppressed. In addition, flow resistance may be decreased by the location of the electrical components in addition to the non-flat portion 24 or the protrusion 46 described above, and the preferable position of the substrate 22 with respect to the gate 44. As a result, more efficient filling of the synthetic resin material MJ and high quality of the housing 12 may be achieved.

The electrical components on the substrate 22 may be disposed, in such a manner that a flow path having a width equal to or greater than a predetermined width through which the synthetic resin material MJ flows is formed, in addition to the disposition of the package components (large components 32) apart from the gate 44 as described above. In this case, the flow paths may radially extend from the non-flat portion 24. In addition, the electrical component may be disposed such that a surface region orthogonal to the flow direction of the synthetic resin material MJ is small, or the electrical component (for example, component of cylindrical shape) may have a convex surface against the flow direction of the synthetic resin material MJ. With these electrical components, the synthetic resin material MJ may be able to flow more smoothly.

### Second Embodiment

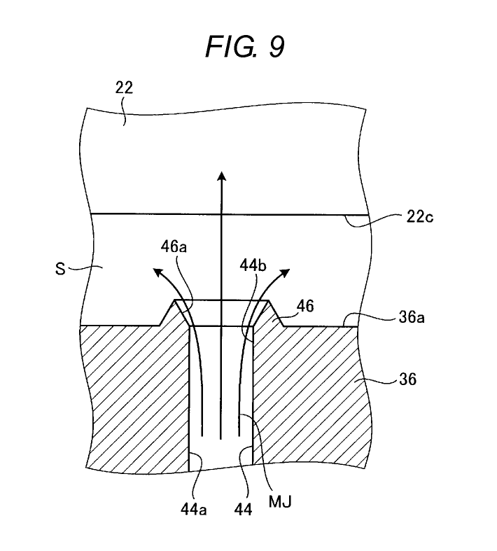

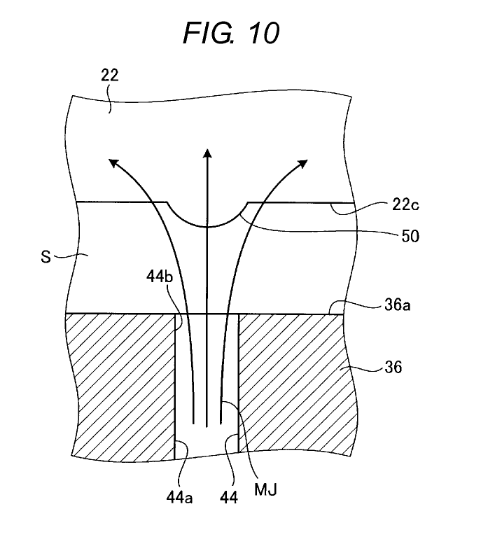

FIG. 9 illustrates a resin flow during molding a housing of an electronic apparatus according to the second embodiment. The second embodiment is the same as the first embodiment, except that the substrate 22 included in the electronic apparatus 10 does not include the non-flat portion 24, which is formed in the position corresponding to the gate 44.

According to the second embodiment, the insert molding mold M has the annular protrusion 46 so as to surround the end portion of the gate outlet 44b. The protrusion 46 is formed of a taper surface wall 46a, in which at least an inner diameter wall of the protrusion 46 on a tip side is larger than on a bottom side (i.e., the inner diameter of the gate outlet 44b). FIG. 9 illustrates a cross-sectional view of the protrusion 46 having a triangular shape as an example.

Even in this case, in the same manner as in the first embodiment, a portion of the synthetic resin material MJ flows along the taper surface wall 46a. That is, when flowing out of the gate 44, the synthetic resin material MJ is deflected along the taper surface wall 46a by viscosity or flow resistance of the synthetic resin material MJ. As a result, a portion of the synthetic resin material flows straight toward the side wall portion 36c (refer to FIG. 5) from the gate 44 and another portion is deflected by the taper surface wall 46a of the protrusion 46 and flows toward the side wall portion 36b and the side wall portion 36d. That is, when the gap portion S is filled with the synthetic resin material MJ, the synthetic resin material MJ may be diffused in a wide range. As a result, the filling efficiency of the synthetic resin material MJ may be increased, and a void or sink marks during completing the molding of the housing 12 may be decreased. In addition, since the shape of the substrate 22 is simplified, a manufacturing cost may be reduced.

### Third Embodiment

FIG. 10 illustrates a flow of a resin during molding a housing of an electronic apparatus according to a third embodiment. In the third embodiment, the substrate 22 in the electronic apparatus 10 includes, for example, a protrusion portion 50, which protrudes in an arch shape as the non-flat portion 24 in a position corresponding to the gate 44. Meanwhile, the insert molding mold M does not include the annular protrusion 46 surrounding the end portion of the gate outlet 44b unlike the first embodiment or the second embodiment.

In the third embodiment, a flow direction of the synthetic resin material MJ flowing out of the gate outlet 44b tends to be deflected by a protruded curved shape of the protrusion portion 50. That is, the flow direction of the synthetic resin material MJ is changed by a shape of the arch shape portion, and the synthetic resin material MJ flows in a direction towards the side wall portion 36b or the side wall portion 36d of the insert molding mold M. As a result, filling efficiency of the synthetic resin material MJ may be increased, and a void or sink marks during completing the molding of the housing 12 may be decreased. Further, since the protrusion portion 50 is formed in a substantially central portion of the side 22c of the substrate 22, the synthetic resin material MJ substantially equally flows towards the side wall portion 36b and towards the side wall portion 36d from the protrusion portion 50. As a result, efficient filling may be performed.

In addition, it is preferable that a height (height in a direction parallel to the side 22c) or a protrusion width (width in a direction parallel to the side 22d) of the protrusion portion 50 is appropriately determined according to a size (distance between the side wall portion 36a and the side wall portion 36c, or distance between the side wall portion 36b and the side wall portion 36d) of the housing 12 to be molded. The diffusion of the synthetic resin material MJ may be adjusted by changing the size of the protrusion portion 50.

In the third embodiment, the annular protrusion 46 may be provided so as to surround the end portion of the gate outlet 44b, in the same manner as in the first embodiment or the second embodiment. In this case, in the same manner as in the first embodiment, more efficient filling of the synthetic resin material MJ may be performed by the diffusion of the synthetic resin material MJ caused by the protrusion 46.

### Fourth Embodiment

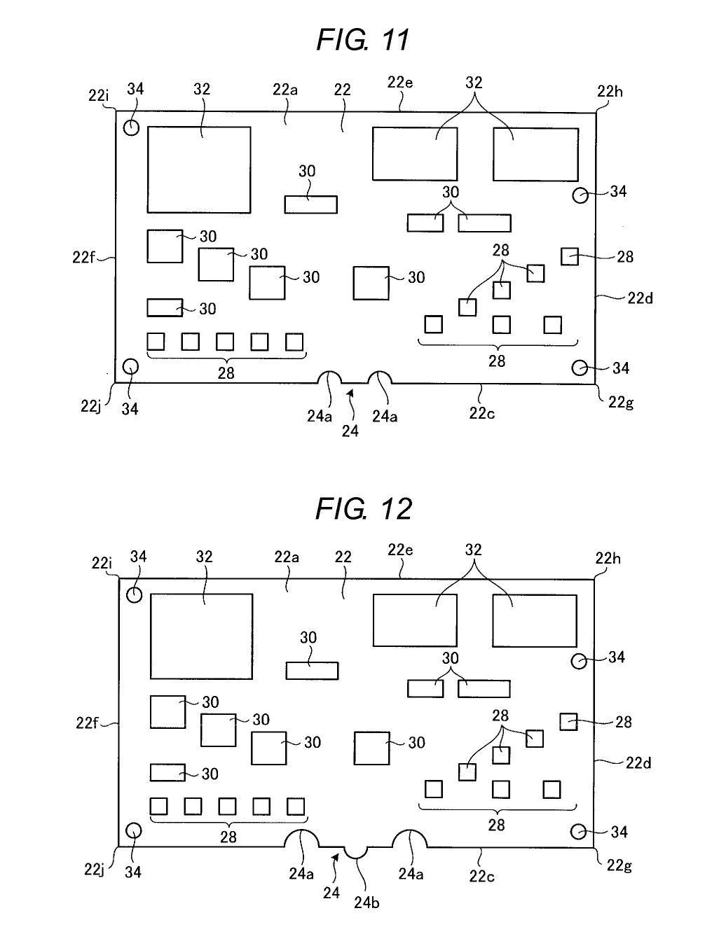

FIG. 11 illustrates a modification example of the non-flat portion 24 of the substrate 22 of the electronic apparatus 10 according to a fourth embodiment. In FIG. 11, the non-flat portion 24 includes a plurality of convex portions 24a (for example, two convex portions) of an arch shape in a central portion (second intermediate portion) of the end portion 22c. According to the fourth embodiment, by changing the shape of the non-flat portion 24, different flow of the synthetic resin material MJ and thus different diffusion effect of the synthetic resin material MJ may be obtained.

### Fifth Embodiment

FIG. 12 illustrates a modification example of the non-flat portion 24 of the substrate 22 of the electronic apparatus 10 according to a fifth embodiment. In FIG. 12, the non-flat portion 24 includes a plurality of concave portions and a convex portion (for example, two concave portions 24a, one convex portion 24b between the two concave portions) of an arch shape in a central portion (second intermediate portion) of the end portion 22c. According to the fifth embodiment, by changing the shape of the non-flat portion 24, different flow of the synthetic resin material MJ and thus different diffusion effect of the synthetic resin material MJ may be obtained.

### Sixth Embodiment

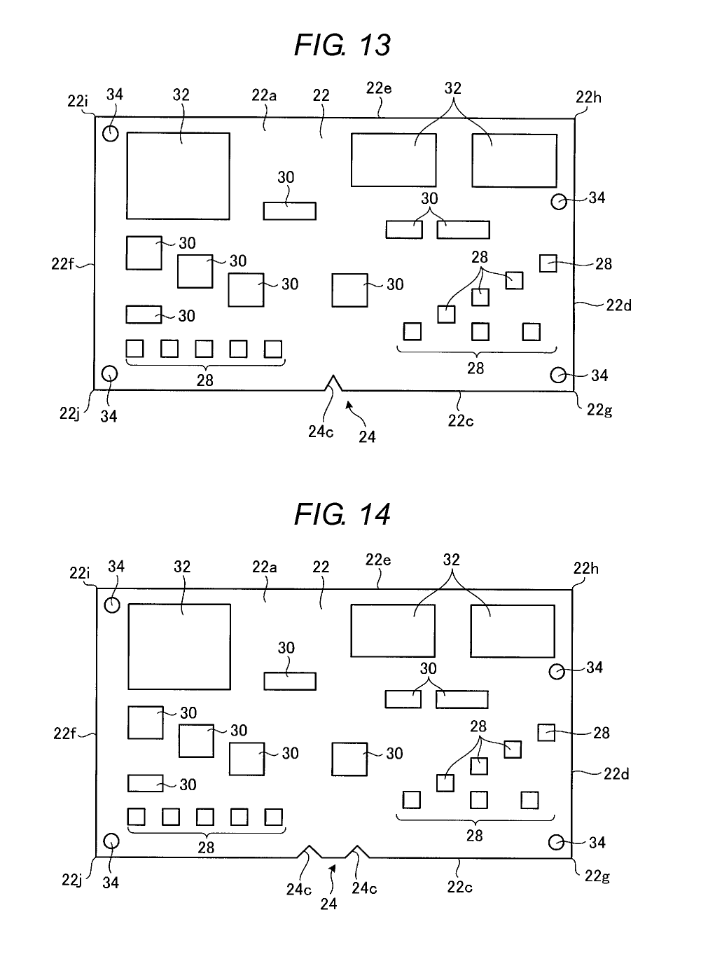

FIG. 13 illustrates a modification example of the non-flat portion 24 of the substrate 22 of the electronic apparatus 10 according to a sixth embodiment. In FIG. 13, the non-flat portion 24 includes a concave portion 24c of a triangular shape in a central portion (second intermediate portion) of the end portion 22c. According to the sixth embodiment, by changing the shape of the non-flat portion 24, different flow of the synthetic resin material MJ and thus different diffusion effect of the synthetic resin material MJ may be obtained.

### Seventh Embodiment

FIG. 14 illustrates a modification example of the non-flat portion 24 of the substrate 22 of the electronic apparatus 10 according to a seventh embodiment. In FIG. 14, the non-flat portion 24 includes a plurality of concave portions 24c (for example, two concave portions) of a triangular shape in a central portion (second intermediate portion) of the end portion 22c. According to the seventh embodiment, by changing the shape of the non-flat portion 24, different flow of the synthetic resin material MJ and thus different diffusion effect of the synthetic resin material MJ may be obtained.

### Eighth Embodiment

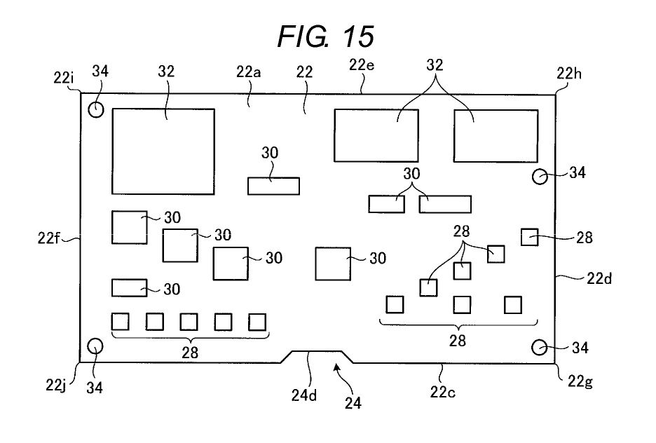

FIG. 15 illustrates a modification example of the non-flat portion 24 of the substrate 22 of the electronic apparatus 10 according to the eighth embodiment. In FIG. 15, the non-flat portion 24 includes a concave portion 24d of a trapezoidal shape in a central portion (second intermediate portion) of the end portion 22c. According to the eighth embodiment, by changing the shape of the non-flat portion 24, different flow of the synthetic resin material MJ and thus different diffusion effect of the synthetic resin material MJ may be obtained.

The shapes of the non-flat portion 24 illustrated in FIG. 11 to FIG. 15 are examples. Since flow resistance of the synthetic resin material MJ depends on a type, number, position, or the like of the electrical components mounted on the substrate 22, it is preferable that the number or the shape of the concave or convex portions is appropriately determined.

### Ninth Embodiment

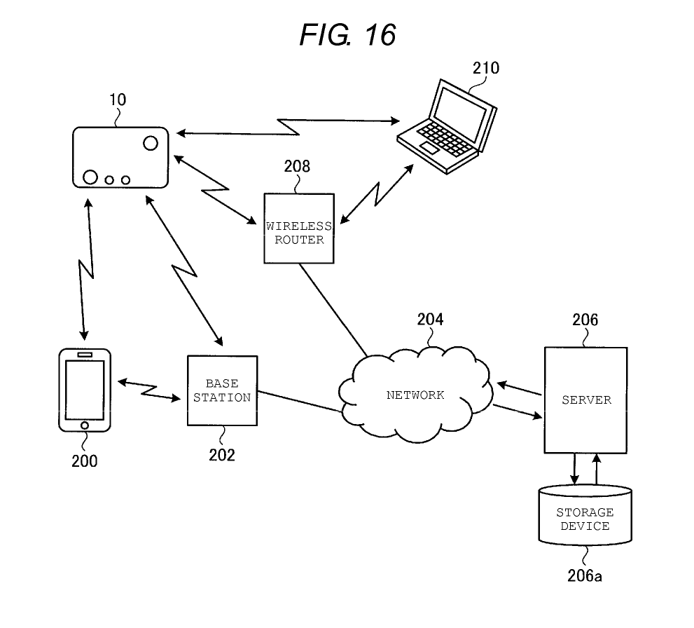

A usage example of the electronic apparatus 10 according to the above-described embodiments will be described with reference to FIG. 16. When the electronic apparatus 10 detects, a biological signal (potential, cardiac potential, detected value) for an electrocardiogram, the electronic apparatus 10 transmits biological information (information, transmission information), which is obtained based on the detected biological signal, to an external apparatus. For example, the electronic apparatus 10 transfers the biological information (information, transmission information) to a communication terminal 200 (mobile phone, smart phone) being carried by a user through an embedded communication function, such as Bluetooth. Here, the communication terminal 200 may transmit the acquired biological information to a server 206 which is an external apparatus, through a base station 202 or a network 204. Alternatively, the electronic apparatus 10 may transmit the detected biological signal as it is towards the server 206.

In addition, when the electronic apparatus 12 includes a connection function to the network 204 such as a Wi-Fi communication function, the electronic apparatus 10 may transmit the biological information (biological signal) to the server 206 through the base station 202 and the network 204. When the electronic apparatus 12 is connectable to a wireless LAN, the electronic apparatus 10 may transmit the biological information to the server 206 through a wireless router 208 and the network 204. The electronic apparatus 10 may transmit the biological information through the wireless router 208 via a personal computer 210.

In the above-describe example, a communication network (electrical communication circuit) using wireless is described, but a communication network using a wire may be used. The communication network includes, for example, a router, a modem, an access point, a cable, and the like. In addition, each apparatus may transmit and receive data according to a predetermined communication protocol.

Each time the electronic apparatus 12 acquires the biological information, the electronic apparatus 10 may transmit the acquired information to the server 206. Alternatively, the electronic apparatus 12 may transmit the information after a predetermined amount of signal is accumulated. Further, the electronic apparatus 10 may transmit the information every predetermined time period, and may transmit the information at a desired timing of a user in accordance with an operation of the electronic apparatus 10.

When transmitting the biological information to the server 206, the electronic apparatus 10 may transmit the biological information together with personal ID and password which are provided to each user, such that each user may be identified by the server 206. It is also possible to transmit the information without specifying an individual person, and using a guest ID.

When the server 206 acquires biological information, the server 206 stores the biological information in a storage device 206a, and performs processing according to the biological information. For example, when the biological information indicates a cardiac potential, the server 206 generates an electrocardiogram. Furthermore, the server 206 performs analysis of the electrocardiogram and generates health condition information based on the analysis. In addition, when the biological information indicates a pulse wave signal or a temperature signal, the server 206 converts the signal into a pulse or body temperature, and generates the health condition information based on the pulse or the body temperature.

When the server 206 generates the health condition information, the server 206 generates an electrocardiogram based on the biological information obtained during a predetermined time period, and generates a graph of a pulse or body temperature. In addition, the server 206 may generate diagnostic information based on the generate data. In addition, when the user continually transmits the biological information to the server 206 using a personal ID, the server 206 may perform diagnosis of a long-term health condition based on a comparison of a past analysis result or diagnostic information and a newest analysis result or diagnostic information, and may create generate advice or the like as health information.

The server 206 stores the generated health diagnosis information in the storage device 206a, and returns the health diagnosis information to the user who sent the biological information through the network 204.

For example, when the user transmits the biological information through the communication terminal 200, the health diagnosis information is displayed on a display screen of the communication terminal 200.

When the user directly transmits the biological information to the server 206, using the communication function of the electronic apparatus 10, the server 206 transmits the health diagnosis information to the electronic apparatus 10. In response to receiving the health diagnosis information, the electronic apparatus 10 transfers the health diagnosis information to the communication terminal 200 or the personal computer 210 that user owns, and the health diagnosis information is displayed on a display screen of the communication terminal 200 or the personal computer 210.

In the same manner, when the electronic apparatus 10 transmits the biological information to the server 206 through the wireless router 208, the health diagnosis information may be transmitted to the personal computer 210 of the user, and the health diagnosis information may be displayed on the display screen of the personal computer 210 of the user.

The health diagnosis information transmitted from the server 206 may be stored in the communication terminal 200 or the personal computer 210. The biological signal detected by the electronic apparatus 10 may be stored in the communication terminal 200 or the personal computer 210 as original data.

In the present embodiment, biological information based on a biological signal detected by the electronic apparatus 10 is transmitted to server 206 and is analyzed by the server 206. As another embodiment, a dedicated program may be installed in the communication terminal 200 or the personal computer 210, and the electrocardiogram or the health diagnosis information may be generated by the communication terminal 200 or the personal computer 210. In addition, a simple analysis or simple health diagnosis information may be generated by the communication terminal 200 or the personal computer 210, and more detailed analysis or health diagnosis information may be generated by the server 206 according to a request of a user.

As described above, an electronic apparatus according to one or more embodiments includes a substrate having an edge including a non-flat portion, a plurality of electronic units disposed on a surface of the substrate, and a molded resin member covering the substrate that has the plurality of electronic units thereon and having a gate scar at a position facing the non-flat portion of the edge. According to this configuration, by the non-flat portion, a flow direction of the synthetic resin material may be changed. That is, the synthetic resin material is diffused in accordance with the shape of the non-flat portion. As a result, the synthetic resin material may spread widely and a void or sink marks may be decreased.

In addition, the trace of the electronic apparatus according to the embodiment may include a concave portion. To form such a concave portion, when the housing is molded, a molding mold that includes a protrusion extending toward the non-flat portion is used. In this case, the synthetic resin material flows along the protrusion, and thus diffusion of the synthetic resin material may be promoted.

In addition, the concave portion of the electronic apparatus according to the embodiment may be annular. According to this configuration, the synthetic resin material flowing out of the gate annularly spreads, and a diffusion efficiency of the synthetic resin material may be increased.

In addition, the trace of the electronic apparatus according to the embodiment may include a third end portion on a side opposite to the second surface rather than the first surface in a view in a first direction along the first surface or the second surface, and a fourth end portion on a side opposite to the first surface rather than the second surface in a view in the first direction. Further, the trace may be provided between the third end portion and the fourth end portion. According to this configuration, the synthetic resin material may be diffused on the first surface side and the second surface side of the substrate, and thus the filling efficiency of the synthetic resin material may be increased.

In addition, the outer surface of the electronic apparatus according to the embodiment may include a third surface positioned on a side opposite to the second end portion, which is opposite to the first end portion. Further, the trace may be provided in a first intermediate portion between two fifth end portions in front and rear of a second direction along the first end portion, on the third surface. According to this configuration, compared to when the fifth end portion, that is, the trace exists in the end portion on a front side or on a rear side of the second direction on the third surface, the resin can spread uniformly. Thus, the shape of the molded resin may properly reflect the shape of the mold.

In addition, in the electronic apparatus according to the embodiment, the non-flat portion may be provided in a second intermediate portion between two sixth end portions in front and rear of a second direction along the first end portion, in the first end portion. According to this configuration, the resin may spread uniformly between front and rear of the second direction. Thus, the shape of the molded resin may properly reflect the shape of the mold.

In addition, the non-flat portion and the electrodes of the electronic apparatus according to the embodiment may be disposed apart from each other. When the non-flat portion and the electrodes are provided closely, the resin is unlikely to flow between the non-flat portion and the electrodes during resin molding. In contrast, according to this configuration, as the non-flat portion and the electrodes are apart from each other, resin molding failure due to a narrow interval between the non-flat portion and the electrodes may be reduced.

In addition, the electronic apparatus according to the embodiment may further include a first electrical component, which is one of the plurality of electrical components provided in one of the first surface and the second surface, and a second electrical component, which is one of the plurality of electrical components provided on one of the first surface and the second surface. A height of the second electrical component is higher than the first electrical component, and is positioned farther from the non-flat portion than the first electrical component. According to this configuration, compared to a structure in which the second electrical component higher than the first electrical component is close to the non-flat portion, the resin can spread more uniformly. Thus, the shape of the molded resin may properly reflect the shape of the mold.

In addition, a package component functioning as the electrical component of the electronic apparatus according to the embodiment may be positioned closer to the second end portion than the first end portion. According to this configuration, as the synthetic resin material is less likely to contact the package component, filling of the synthetic resin material may become more efficient and easier, and also a void or sink marks may be decreased.

In each embodiment described above, when the insert molding mold M is filled with the synthetic resin material MJ, by injecting a designated amount of the synthetic resin material MJ is into the gap portion S, an electronic apparatus 10 (housing 12) of an aimed shape may be formed. In this case, a gas vent hole through which air is exhausted during the injection of the synthetic resin material MJ into the gap portion S is provided in the insert molding mold M, whereby occurrence of a void or sink marks may be suppressed. In addition, in other embodiments, as illustrated in FIG. 5, the connection portion 44c may be formed to performs vacuum de-aeration of the insert molding mold M. By vacuuming the air in the gap portion S prior to filling or during filling of the synthetic resin material MJ, filling efficiency of the synthetic resin material MJ may be increased, and air contained in the synthetic resin material MJ may be also removed. As a result, a void or sink marks may be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus, comprising:
a substrate having an edge including a non-flat portion;
a plurality of electronic units disposed on a surface of the substrate; and
a molded resin member covering the substrate and the plurality of electronic units thereon and having a gate scar at a position corresponding to the non-flat portion of the edge.

2. The electronic apparatus according to claim 1, wherein
the gate scar includes a recessed portion.

3. The electronic apparatus according to claim 1, wherein
the recessed portion has an annular shape.

4. The electronic apparatus according to claim 1, wherein
the gate scar has a first portion formed on a region of the molded resin member above the substrate and a second portion formed on a region of the molded resin member below the substrate.

5. The electronic apparatus according to claim 4, wherein
the plurality of electronic units is disposed above the substrate, and an area of the first portion is larger than an area of the second portion.

6. The electronic apparatus according to claim 5, further comprising:
an electrode to be placed on a body of a subject for detection of a biological signal, the electrode being disposed below the substrate.

7. The electronic apparatus according to claim 1, wherein
the substrate has a rectangular shape and the edge is along a long side of the substrate, and
the non-flat portion is located at a center portion of the long side.

8. The electronic apparatus according to claim 1, wherein
the non-flat portion includes a protruding portion protruding towards the gate scar.

9. The electronic apparatus according to claim 1, wherein
the non-flat portion includes a recessed portion recessing away from the gate scar.

10. The electronic apparatus according to claim 1, wherein
the plurality of electronic units includes a first electronic unit and a second electronic unit located farther from the non-flat portion than the first electronic unit, and
a height of the second electronic unit is higher than a height of the first electronic unit.

11. The electronic apparatus according to claim 10, wherein
the first and second electronic units are arranged along a line extending from the non-flat portion.

12. The electronic apparatus according to claim 10, wherein
the plurality of electronic units further includes a third electronic unit located farther from the non-flat portion than the second electronic unit, and
a height of the third electronic unit is higher than the height of the second electronic unit.

13. An electronic apparatus, comprising:
a substrate;
a plurality of electronic units disposed on a surface of the substrate; and
a molded resin member covering the substrate that has the plurality of electronic units thereon and having a gate scar on a surface thereof, the gate scar having a first portion formed on a region of the molded resin member above the substrate and a second portion formed on a region of the molded resin member below the substrate.

14. The electronic apparatus according to claim 13, wherein
the plurality of electronic units is disposed above the substrate, and an area of the first portion is larger than an area of the second portion.

15. The electronic apparatus according to claim 14, further comprising:
an electrode to be placed on a body of a subject for detection of a biological signal, the electrode being disposed below the substrate.

16. The electronic apparatus according to claim 15, wherein
a height of the electrode is lower than a height of one of the plurality of electronic units that has a largest height.

17. The electronic apparatus according to claim 13, wherein
the plurality of electronic units includes a first electronic unit and a second electronic unit located farther from the gate scar than the first electronic unit is, and
a height of the second electronic unit is higher than a height of the first electronic unit.

18. An electronic apparatus, comprising:
a substrate;
first and second electronic units disposed on a surface of the substrate; and
a molded resin member covering the substrate that has the first and second electronic units thereon and having a gate scar on a surface thereof, wherein
the second electronic unit is located farther from the gate scar than the first electronic unit is, and
a height of the second electronic unit is higher than a height of the first electronic unit.

19. The electronic apparatus according to claim 18, wherein
the first and second electronic units are arranged along a line extending from the gate scar.

20. The electronic apparatus according to claim 18, further comprising:
a third electronic unit disposed on the surface of the substrate and located farther from the gate scar than the second electronic unit is, wherein
a height of the third electronic unit is higher than the height of the second electronic unit.
